(19) United States
(12) Patent Application Publication
(10) Pub. No.: US 2010/0052767 A1
(43) Pub. Date: Mar. 4, 2010

(54) SEMICONDUCTOR MODULE

(75) Inventor: Satoru NATE, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/552,850

(22) Filed: Sep. 2, 2009

(30) Foreign Application Priority Data
Sep. 2, 2008 (JP) 2008-225169

(51) Int. Cl. H03K 17/00

(52) U.S. Cl. 327/407

(57) ABSTRACT

A semiconductor module is provided. Multiple external terminals are connected to an external circuit. Each semiconductor chip includes multiple pads. Wiring lines connect the multiple pads provided to each of the multiple semiconductor chips and the corresponding external terminals or corresponding different pads, respectively. Multiple input terminals of a switch are connected to corresponding internal nodes included within the semiconductor module, and an output terminal thereof is connected to a monitoring terminal provided as an external terminal. The switch makes a connection between the output terminal and one input terminal selected from among the multiple input terminals.

### BACKGROUND OF THE INVENTION

1. Field of the Invention

The present invention relates to a semiconductor module having a configuration in which a semiconductor chip and a peripheral circuit thereof are monolithically integrated in the form of a single unit.

2. Description of the Related Art

Semiconductor modules, which are obtained by making a combination of multiple semiconductor chips and electronic components in the form of a module, are being actively developed. FIG. 1 is an example configuration of an ordinary semiconductor module. A semiconductor module 200 includes semiconductor chips 202a and 202b, chip capacitors C, chip resistors R, and so forth, therewithin as built-in components, which are monolithically integrated so as to form a single unit. The semiconductor module 200 includes multiple external terminals 204 which allow electric power to be received from an external power supply, or which allows a signal to be transmitted or received. It should be noted that, in FIG. 1 or other drawings described later, the connection arrangement between the external terminals, semiconductor chips, chip resistors, and chip capacitors will be described for exemplary purpose only, and is by no means intended to provide a particular function.

In general, in a step before the semiconductor chips 202a and 202b are mounted on the semiconductor module 200, a DC test, function test, etc., are executed for these semiconductor chips 202a and 202b. In this step, chip selection is performed based upon the quality, and only semiconductor chips exhibiting ensured stand-alone quality are mounted on the semiconductor module 200. After the completion of fabrication of the semiconductor module 200, various operation tests are executed in a state close to the actual operation state.

In the operation test step for testing the semiconductor module 200, the state of wiring lines or nodes (which will collectively be referred to as “internal nodes” in the present specification) connected to an external terminal 204 can be tested by an external circuit. Alternatively, an external signal can be supplied to such an internal node. However, the state of the wiring line which has not been connected to the external terminal 204 cannot be monitored by an external circuit. For example, in a case in which it is desired that the state of a path of the wiring line L1 that connects a certain pad P1 provided to the semiconductor chip 202a and a corresponding pad P2 provided to the semiconductor chip 202b be monitored, or in a case in which it is desired that a voltage or an electric current be supplied via the wiring line, there is a need to provide an additional external test terminal which is not involved in the original operation.

An increase in the internal nodes used in the test step to monitor the state thereof or to supply a signal requires an increased number of external terminals for the test step, leading to a problem of difficulty in designing the semiconductor module 200 with a small size.

### SUMMARY OF THE INVENTION

The present invention has been made in view of such a situation. It is an exemplary purpose of an embodiment thereof to provide a semiconductor module with a reduced size.

An embodiment of the present invention relates to a semiconductor module. The semiconductor module includes: multiple external terminals to be connected to an external circuit; multiple semiconductor chips each of which includes multiple pads; multiple wiring lines which connect the multiple pads, provided to each of the multiple semiconductor chips, to the corresponding external terminals or the corresponding different pads, respectively; and a switch having multiple input terminals each connected to a corresponding internal node included within the semiconductor module, and an output terminal which is connected to one of the multiple external terminals, which makes a connection between the output terminal and one input terminal selected from among the multiple input terminals.

With such an embodiment, multiple internal nodes can be accessed by switching the state of the switch. Specifically, the state of each internal node can be tested via a single external terminal. Alternatively, a signal can be supplied to each of the multiple internal nodes via a single external terminal. As a result, there is no need to provide multiple external test terminals in increments of the internal nodes, thereby preventing the size of the semiconductor module from being increased. It should be noted that the relation between the input terminals and the output terminal of the switch has been described as one form. Accordingly, in some cases, a signal input via the input terminal is output via the output terminal. In some cases, a signal input via the output terminal is output via the input terminal.

Also, at least one of the multiple external terminals may be assigned as a control terminal. Also, the switch may be controlled according to a control signal input via the control terminal from a circuit external to the semiconductor module.

Also, at least one of the multiple external terminals may be assigned as a control terminal. Also, at least one of the multiple semiconductor chips may include a control circuit which controls the switch according to a control signal input via the control terminal from a circuit external to the semiconductor module.

Also, the control terminal may be a shared terminal which is also used in the normal operation of the semiconductor module as a terminal which allows a signal involved in the original operation of the semiconductor module to be input or output.

With such an arrangement, there is no need to provide an additional external terminal for controlling the switch, thereby providing a semiconductor module with a further reduced size.

Also, the switch may be configured such that it can be set to an OFF state in which all the multiple input terminals are electrically disconnected from the output terminal.

Also, the external terminal connected to the output terminal of the switch may be a shared terminal which is also used in the normal operation of the semiconductor module as a terminal which allows a signal involved in the original operation of the semiconductor module to be input or output. Also, the switch may be set to the OFF state in the normal operation.

Also, the switch may be arranged such that the distance between the multiple input terminals of the switch and the corresponding multiple internal nodes is smaller than the distance between the output terminal of the switch and the external terminal that corresponds to the output terminal.

With such an arrangement, the distance between the multiple internal nodes and the switch is small, thereby reducing the impedance due to the parasitic resistance and parasitic capacitance which are effects of the switch side on each internal node. Thus, such an arrangement suppresses the effects of the switch on the original circuit operation.

Also, at least one of the multiple internal nodes may be provided on a path of a wiring line that connects a pad provided to a first semiconductor chip and a pad provided to a second semiconductor chip.

Another embodiment of the present invention also relates to a semiconductor module. The semiconductor module includes: multiple external terminals to be connected to an external circuit; a semiconductor chip which includes multiple pads; multiple wiring lines which connect the multiple pads to the corresponding external terminals or the corresponding different pads, respectively; and a switch having multiple input terminals via which multiple signals that occur at multiple internal nodes included within the semiconductor module are input, and an output terminal which is connected to one external terminal selected from among the multiple external terminals, and via which a signal selected from among the multiple singles is output.

Also, at least one of the multiple internal nodes may be arranged in the vicinity of a given pad provided to the semiconductor chip, on a path of a wiring line that connects the given pad and the external terminal that corresponds to the given pad. Also, the external terminal that corresponds to the given pad may be connected to a constant current source in a test step for testing the semiconductor module. Also, the external terminal connected to the output terminal of the switch may be connected, in the test step for testing the semiconductor module, to a voltmeter which measures the electric potential at the given pad.

Such an arrangement reduces the number of the external test terminals, thereby providing a module with a reduced size.

In some cases, an electric potential should be measured at a position in the vicinity of a pad of the semiconductor chip. In a case in which a current is applied to a wiring line via an external terminal connected to a current supply, voltage drop occurs at the wiring line. If the voltage is measured by a voltmeter connected to another external terminal, the electric potential, which has dropped from the electric potential at a position in the vicinity of the pad to be measured, is measured. By connecting the input terminal of the switch to a node in the vicinity of the pad, such an arrangement is capable of measuring the electric potential with high precision without effects of the voltage drop.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a diagram which shows an example configuration of an ordinary semiconductor module;

FIG. 2 is a diagram which shows a configuration of a semiconductor module according to an embodiment;

FIG. 3A through FIG. 3C are diagrams which show the configurations of semiconductor modules according to a first modification through a third modification, respectively; and

FIG. 4 is a diagram which shows another example configuration of the semiconductor module according to the embodiment.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not affect the electric connection therebetween, in addition to a state in which the member A is physically and directly connected to the member B. In the same way, the state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

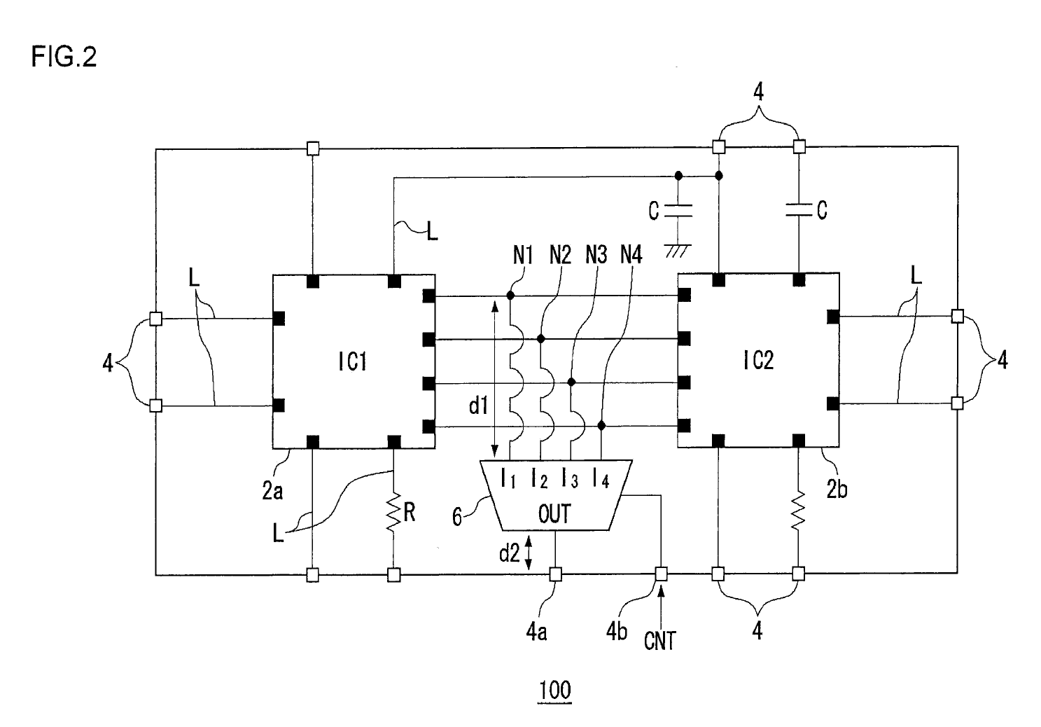

FIG. 2 is a diagram which shows a configuration of a semiconductor module 100 according to an embodiment. A semiconductor module 100 includes multiple semiconductor chips 2a and 2b, multiple external terminals 4, monitoring terminals 4a, control terminals, a switch 6, and multiple wiring lines L.

In the step in which the semiconductor module 100 is mounted on a printed-circuit board or the like, the multiple external terminals 4 are connected to an external circuit. Each of the multiple semiconductor chips 2a and 2b includes multiple pads P. The multiple wiring lines L connect the multiple pads P, which are respectively provided to the multiple semiconductor chips 2a and 2b, to the corresponding external terminals 4 or the different corresponding pads P.

The switch 6 includes multiple input terminals I₁ through I₄, and an output terminal OUT. FIG. 2 shows an arrangement in which the switch 6 includes four input terminals. However, the switch 6 may include a desired number of input terminals. The four input terminals I₁ through I₄ included in the switch 6 are connected to the corresponding internal nodes N1 through N4 included within the semiconductor module 100, respectively. The output terminal OUT of the switch 6 is connected to a particular external terminal (which will be referred to as “monitoring terminal” hereafter) 4a selected from among the multiple external terminals 4.

For example, each of the multiple internal nodes N1 through N4 is provided on a path of the wiring line L that connects a corresponding pad P provided to the first semiconductor chip 2a and a corresponding pad P provided to the second semiconductor chip 2b. Such wiring lines L are not connected to the external terminals 4. Accordingly, the state of such a wiring line L cannot be directly measured using an external circuit. Furthermore, an external signal cannot be supplied to such a wiring line L. By connecting the internal nodes provided to such wiring lines L to the input terminals of the switch 6, such an arrangement enables the state of such an internal node to be measured, or enables a signal to be supplied to such an internal node. It should be noted that the internal nodes N1 through N4 may be provided at desired positions in the semiconductor module 100.

The switch 6 electrically connects one input terminal selected from among the multiple input terminals I₁ through I₄ and the output terminal OUT.

One external terminal is selected as a control terminal 4b from among the multiple external terminals 4. The electrical connection state of the switch 6 is controlled according to a control signal CNT input via the control terminal 4b from a circuit external to the semiconductor module 100. The transmission method or the signal format of the control signal CNT are not restricted in particular.

The switch 6 is preferably provided in the vicinity of the multiple internal nodes N1 through N4, rather than the monitoring terminal 4a. In other words, the switch 6 is preferably arranged such that the distance d1 between the multiple input terminals I₁ through I₄ and the multiple internal nodes N1 through N4 is smaller than the distance d2 between the output terminal OUT of the stitch 6 and the corresponding external terminal (monitoring terminal) 4a. It should be noted that FIG. 2 shows an arrangement in which d2 is smaller than d1. However, in practice, an arrangement in which d1 is smaller than d2 is preferable.

This is because the wiring lines Lp that connect the multiple input terminals I₁ through I₄ and the multiple input nodes N1 through N4 lead to parasitic impedance which affects the wiring lines involved in the original functions, i.e., the wiring lines L that connect the pads P1 provided to the semiconductor chip 2a and the pads P2 provided to the semiconductor chip 2b. Reduction in the distance d1 reduces the parasitic impedance, thereby reducing the effects of the switch 6 and the wiring lines Lp on the circuit operation in the normal operation of the semiconductor module 100.

The above is the configuration of the semiconductor module 100. Next, description will be made regarding a test step for the semiconductor module 100.

When the control signal CNT is supplied to the control terminal 4b from an external circuit, which instructs the switch 6 to select an input terminal according to a user's instruction, the monitoring terminal 4a is electrically connected to an internal node N that corresponds to the input terminal I thus selected. In this state, the signal that occurs at the internal node N can be measured via the monitoring terminal 4a. Alternatively, a desired signal can be supplied to the internal node N from an external terminal.

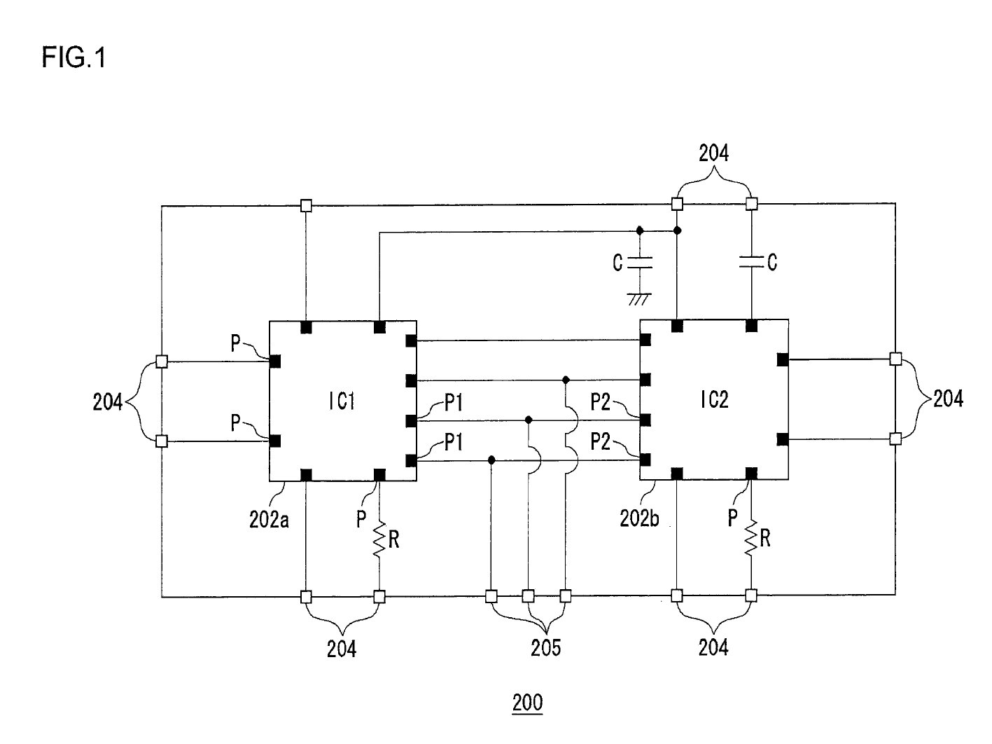

FIG. 2 shows an arrangement including two external terminals 4 provided without involving the original operation of the semiconductor module 100, i.e., the monitoring terminal 4a and the control terminal 4b. If the state of each of the four internal nodes were to be measured in the architecture shown in FIG. 1, or if a signal were to be supplied to each of the four internal nodes in the architecture shown in FIG. 1, such an arrangement would require four external terminals. As described above, the semiconductor module 100 according to the embodiment requires a reduced number of external terminals 4, thereby allowing the semiconductor module 100 to be designed with a smaller size.

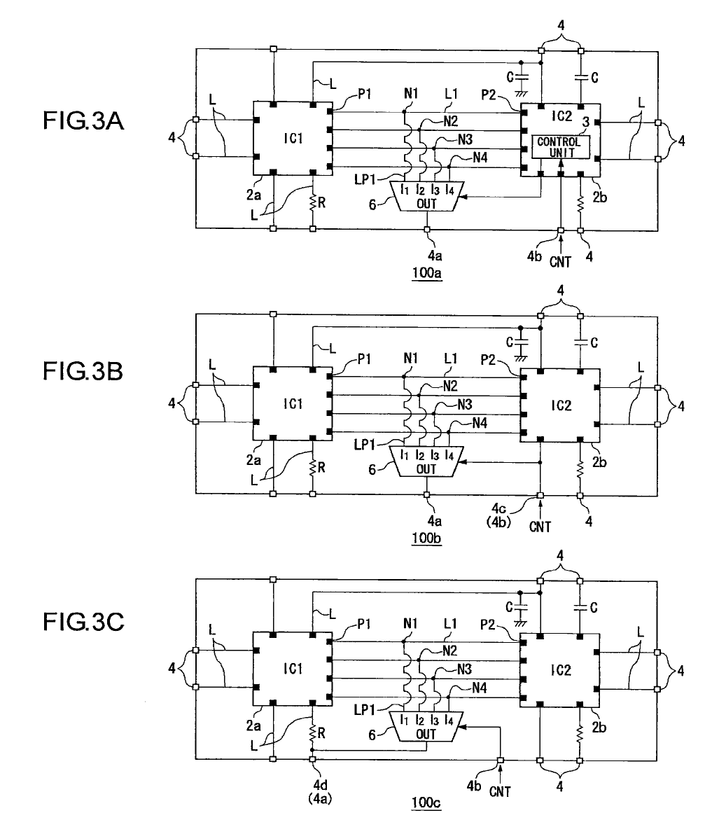

Subsequently, description will be made regarding modifications of the semiconductor module 100. FIG. 3A through FIG. 3C are diagrams which show the configurations of the semiconductor modules according to a first modification through a third modification.

In the first modification shown in FIG. 3A, the semiconductor chip 2b includes a control circuit 3 as a built-in component. The control circuit 3 controls the switch 6 according to a control signal CNT input via the control terminal 4b from a circuit external to the semiconductor module 100a.

With such a modification, a single interface may be shared by the operation for supplying the control signal CNT to the control circuit 3 and the operation for supplying a control signal for controlling the original functions of the semiconductor chip 2b. For example, in a case in which the semiconductor chip 2b includes an I2C (Inter IC) bus type interface which enables the semiconductor chip 2b to communicate with an external processor, which is provided as the original function of the semiconductor chip 2b, such an arrangement is capable of controlling the switch 6 using a commands provided to the I2C. With such an arrangement, the terminal for controlling the original function of the semiconductor chip 2b can be provided as a shared control terminal which is also used as the control terminal 4b. Thus, such an arrangement reduces the number of the external terminals 4 as compared with an arrangement shown in FIG. 2.

FIG. 3B is a diagram which shows the configuration of a semiconductor module 100b according to a second modification. With the present modification, an external terminal 4c, via which a signal involved in the original function of the semiconductor module 100b is input or output in the normal operation of the semiconductor module 100b, also provides a function as the control terminal 4b for the switch 6. That is to say, the switch 6 can be controlled in the test step according to the control signal CNT input via the external terminal 4c. On the other hand, in the normal operation, a signal for controlling the semiconductor chip 2b is input to the external terminal 4c. Alternatively, a signal can be output from the semiconductor chip 2b via the external terminal 4c. For example, in a case in which several external terminals are provided for supplying the ground potential to the semiconductor chip 2b, one selected from among the external terminals may be used as the external terminal 4c in the test step. Such a modification also reduces the number of the external terminals.

In a semiconductor module 100c according to a third embodiment shown in FIG. 3C, the switch 6 can be set to an OFF state in which all the multiple input terminal I₁ through I₄ are electrically disconnected from the output terminal OUT. The monitoring terminal 4a, which is connected to the output terminal OUT of the switch 6, is provided as a shared terminal which can also be used as the terminal 4d via which a signal involved in the original function of the semiconductor module 100c is input or output.

With the present modification, the switch 6 is set to the OFF state in the normal operation state. Thus, the monitoring terminal 4a is provided as a shared terminal which can also be used as the different external terminal 4d without interfering with the normal operation, thereby reducing the number of the external terminals.

A desired combination of the above-described arrangements shown in FIG. 2 and FIG. 3A through FIG. 3C is also effective as an embodiment of the present invention. For example, an arrangement may be made by making a combination of either technique shown in FIG. 3A or FIG. 3B with the technique shown in FIG. 3C. Such an arrangement allows the states of the multiple internal nodes to be measured, or allows signals to be supplied to the multiple internal nodes, without a need to provide the monitoring terminal 4a and the control terminal 4b in addition to the external terminals 4 provided to the semiconductor module 100 according to the original purpose.

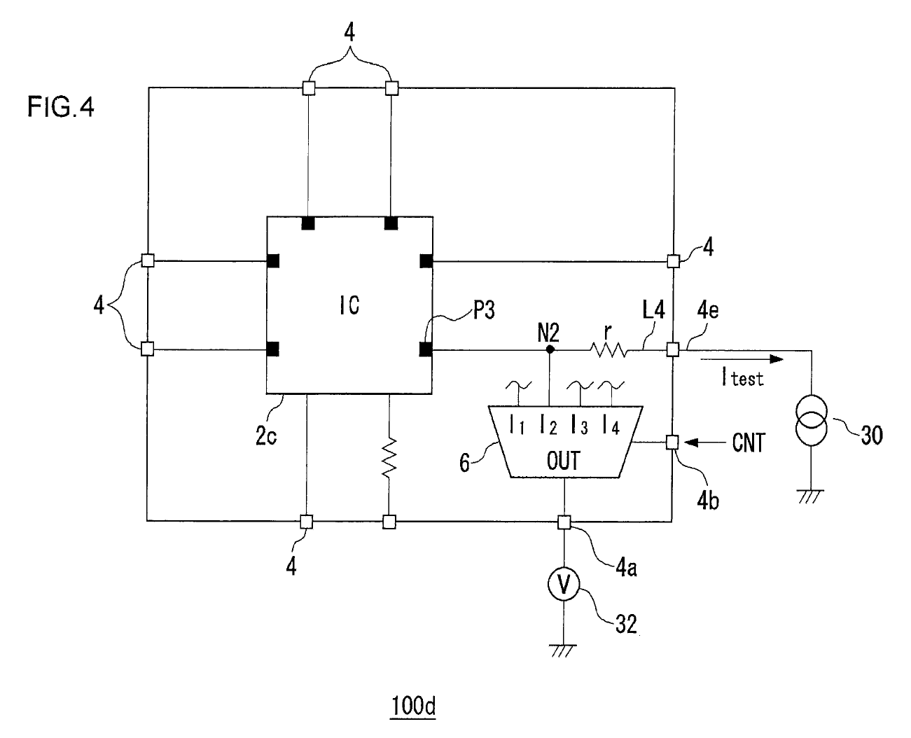

FIG. 4 is a diagram which shows a semiconductor module 100d having anther example configuration according to the embodiment. The present invention can be applied to a semiconductor module including a single semiconductor chip.

An internal node N2 connected to one input terminal I₂ selected from among the multiple input terminals of the switch 6 included in the semiconductor module 100d is provided on a path of a wiring line L4 that connects a pad P3 provided to a semiconductor chip 2c and an external terminal 4e that corresponds to the pad P3. The wiring line L4 has effective impedance (resistance component) r. For the reason described below, the internal node N2 is provided in the vicinity of the pad P3. It should be noted that each of the other input terminals I₁, I₃, and I₄ is connected to a corresponding internal node in the semiconductor module 100d.

In the test step for the semiconductor module 100d, a constant current source 30 is connected to the external terminal 4e that corresponds to the given pad P3 The constant current source 30 draws a predetermined test current Itest via the pad P3 provided to the semiconductor chip 2c. If the wiring line L4 has a sufficiently small resistance component, or if the test current Itest is sufficient small, the voltage drop due to the resistance component r is sufficiently small. Accordingly, the electric potential at the external terminal 4e matches the electric potential at the pad P3. Accordingly, the electric potential at the pad P3 can be measured by measuring the electric potential at the external terminal 4e without troublesome measurement of the electric potential at the internal node N2. However, in a case in which the voltage drop due to the resistance component r is high, the electric potential measured at the external terminal 4e does not match the electric potential measured at the pad P3.

In the semiconductor module 100d shown in FIG. 4, the internal node N2 is arranged in the vicinity of the pad P3. Furthermore, the semiconductor module 100d is configured so as to enable the state of the internal node N2 to be accessed from the monitoring terminal 4a via the switch 6. Thus, by connecting a voltmeter 32 to the monitoring terminal 4a, such an arrangement is capable of measuring the voltage at the pad P3 with high precision even if the voltage drop has occurred due to the resistance component r.

While the preferred embodiments of the present invention have been described using specific terms, such description is for illustrative purposes only, and it is to be understood that changes and variations may be made without departing from the spirit or scope of the appended claims.

1. A semiconductor module comprising:
a plurality of external terminals to be connected to an external circuit;
a plurality of semiconductor chips each of which comprises a plurality of pads;
a plurality of wiring lines which connect the plurality of pads, provided to each of the plurality of semiconductor chips, to the corresponding external terminals or the corresponding different pads, respectively; and
a switch having a plurality of input terminals each connected to a corresponding internal node included within the semiconductor module, and an output terminal which is connected to one external terminal among the plurality of external terminals, which makes a connection between the output terminal and one input terminal selected from among the plurality of input terminals.

2. A semiconductor module according to claim 1, wherein at least one of the plurality of external terminals is assigned as a control terminal,
and wherein the switch is controlled according to a control signal input via the control terminal from a circuit external to the semiconductor module.

3. A semiconductor module according to claim 1, wherein at least one of the plurality of external terminals is assigned as a control terminal,
and wherein at least one of the plurality of semiconductor chips includes a control circuit which controls the switch according to a control signal input via the control terminal from a circuit external to the semiconductor module.

4. A semiconductor module according to claim 2, wherein the control terminal is a shared terminal which is also used in the normal operation of the semiconductor module as a terminal which allows a signal involved in the original operation of the semiconductor module to be input or output.

5. A semiconductor module according to claim 3, wherein the control terminal is a shared terminal which is also used in the normal operation of the semiconductor module as a terminal which allows a signal involved in the original operation of the semiconductor module to be input or output.

6. A semiconductor module according to claim 1, wherein the switch can be set to an OFF state in which all the plurality of input terminals are electrically disconnected from the output terminal.

7. A semiconductor module according to claim 6, wherein the external terminal connected to the output terminal of the switch is a shared terminal which is also used in the normal operation of the semiconductor module as a terminal which allows a signal involved in the original operation of the semiconductor module to be input or output,
and wherein the switch is set to the OFF state in the normal operation.

8. A semiconductor module according to claim 1, wherein the switch is arranged such that the distance between the plurality of input terminals of the switch and the corresponding plurality of internal nodes is smaller than the distance between the output terminal of the switch and the external terminal that corresponds to the output terminal.

9. A semiconductor module according to claim 1, wherein at least one of the plurality of internal nodes is provided on a path of a wiring line that connects the pad provided to a first semiconductor chip selected from among the semiconductor chips and the pad provided to a second semiconductor chip selected from among the semiconductor chips.

10. A semiconductor module comprising:
a plurality of external terminals to be connected to an external circuit;
a semiconductor chip which comprises a plurality of pads;
a plurality of wiring lines which connect the plurality of pads to the corresponding external terminals or the corresponding different pads, respectively; and
a switch having a plurality of input terminals each connected to a corresponding internal node included within the semiconductor module, and an output terminal which is connected to one of the plurality of external terminals, which makes a connection between the output terminal and one input terminal selected from among the plurality of input terminals.

11. A semiconductor module according to claim 10, wherein at least one of the plurality of internal nodes is arranged in the vicinity of a given pad provided to the semiconductor chip, on a path of the wiring line that connects the given pad and the external terminal that corresponds to the given pad,
and wherein the external terminal that corresponds to the given pad is to be connected to a constant current source in a test step for testing the semiconductor module,
and wherein the external terminal connected to the output terminal of the switch is to be connected, in the test step for testing the semiconductor module, to a voltmeter which measures the electric potential at the given pad.
